(19) United States
(12) Patent Application Publication
(10) Pub. No.: US 2026/0344549 A1
(43) Pub. Date: Oct. 29, 2026

(54) RAPID THERMAL PROCESSING FOR DIRECT BONDING

(71) Applicant: ADEIA SEMICONDUCTOR BONDING TECHNOLOGIES INC., San Jose, CA (US)

(72) Inventors: Dominik Suwito, San Jose, CA (US); Thomas Workman, San Jose, CA (US); Rajesh Katkar, Milpitas, CA (US); Laura Wills Mirkarimi, Sunol, CA (US)

(21) Appl. No.: 19/731,989

(22) Filed: Jul. 6, 2026

Related U.S. Application Data
(63) Continuation of application No. 18/461,290, filed on Sep. 5, 2023.
(60) Provisional application No. 63/374,881, filed on Sep. 7, 2022.

(51) Int. Cl. H10W 99/00; H10W 72/00; H10W 72/90; H10W 80/00; H10W 90/00

(52) U.S. Cl. CPC H10W 99/00; H10W 72/90; H10W 72/019; H10W 80/312; H10W 80/327; H10W 90/792

(57) ABSTRACT

Bonded structures and methods of direct hybrid bonding are disclosed. Non-conductive regions of two elements, such as dies or wafers, are first bonded together to form a bonded structure. Aligned conductive regions of the bonded structure, such as metal pads or traces, are then annealed to expand and bridge a gap between them. The anneal includes rapid thermal processing (RTP), such as with radiant heating. The bond interface between the first and second conductive features includes rapid growth structure(s) indicative of the inclusion of RTP in the anneal. Additional non-RTP anneal phases can also be employed.

### CROSS-REFERENCE TO RELATED APPLICATIONS

This application is a continuation of U.S. Non-Provisional patent application Ser. No. 18/461,290, filed Sep. 5, 2023, which claims priority to U.S. Provisional Patent Application No. 63/374,881, filed Sep. 7, 2022, both titled “RAPID THERMAL PROCESSING FOR DIRECT BONDING,” the entire contents of each of which are hereby incorporated herein by reference.

### BACKGROUND

### Field

The field relates to bonded structures and methods of forming a direct hybrid bonded structure using rapid thermal processing.

### Description of the Related Art

Microelectronic elements, such as integrated device dies or chips, may be mounted or stacked on other elements thereby forming a bonded structure. Hybrid bonding involves directly bonding non-conductive features (e.g., inorganic dielectrics) of different elements together, without intervening adhesives, while also directly bonding conductive features (e.g., metal pads or lines) of the elements together. For example, a microelectronic element can be mounted to a carrier, such as a package substrate, an interposer, a reconstituted wafer or element, etc. As another example, a microelectronic element can be stacked on top of another microelectronic element, e.g., a first integrated device die can be stacked on a second integrated device die. Each of the microelectronic elements can have conductive pads for mechanically and electrically bonding the elements to one another. There is a continuing need for improved methods for forming the bonded structure.

### BRIEF DESCRIPTION OF THE DRAWINGS

Specific implementations will now be described with reference to the following drawings, which are provided by way of example, and not limitation.

FIG. 1A is a schematic cross-sectional side view of two elements prior to direct hybrid bonding.

FIG. 1B is a schematic cross-sectional side view of the two elements shown in FIG. 1A after direct hybrid bonding.

FIG. 2A is a schematic cross-sectional view of a bonded structure, after initial direct bonding of non-conductive regions together, in a rapid thermal processing (RTP) chamber.

FIG. 2B is a schematic perspective view of an RTP system that can be used to anneal the bonded structure after initial bonding of non-conductive regions together.

FIG. 2C is a schematic view of a heating system that moves bonded structures through heating zones.

FIG. 2D is a graph showing an annealing profile of a typical convection anneal process with different stages.

FIG. 2E is a graph showing an annealing profile of an anneal process using the RTP.

FIG. 3A is a schematic cross-sectional side view of a bonded structure prior to annealing.

FIG. 3B is a schematic cross-sectional side view of the bonded structure after annealing, including RTP, to merge conductive features.

FIG. 4A is a schematic cross-sectional side view of the bonded structure similar to that of FIG. 3A after a first annealing process.

FIG. 4B is a schematic cross-sectional side view of the bonded structure of FIG. 4A after a second annealing process.

FIG. 4C is a schematic cross-sectional side view of the bonded structure of FIG. 4B after a third annealing process.

FIG. 5A is a flow chart showing a method of forming a bonded structure according to an embodiment.

FIG. 5B is a flow chart showing another method of forming a bonded structure according to an embodiment.

FIG. 6A is a schematic cross-sectional side view of a bonded structure prior to annealing.

FIG. 6B is a schematic cross-sectional side view of the bonded structure after a first annealing process.

FIG. 6C is a schematic cross-sectional side view of the bonded structure after a second annealing process.

FIG. 6D is a schematic cross-sectional side view of the bonded structure after a third annealing process.

FIGS. 7A-7F show annealing temperatures and annealing times of various annealing processes.

FIG. 8 is a chart showing experimental results indicating reliability of bonded structures formed using various methods disclosed herein.

FIGS. 9A-9D illustrate micrographs of bonded elements at various stages of annealing to illustrate experimental results.

FIG. 10 schematically shows a thermal treatment system according to an embodiment.

FIG. 11A schematically shows a thermal treatment system according to another embodiment in a first state (a heating cycle).

FIG. 11B shows the thermal treatment system of FIG. 11A in a second state (a cooling cycle).

### DETAILED DESCRIPTION OF THE PREFERRED EMBODIMENT

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same. Direct bonding can also involve bonding of multiple materials on one element to multiple materials on the other element (e.g., hybrid bonding).

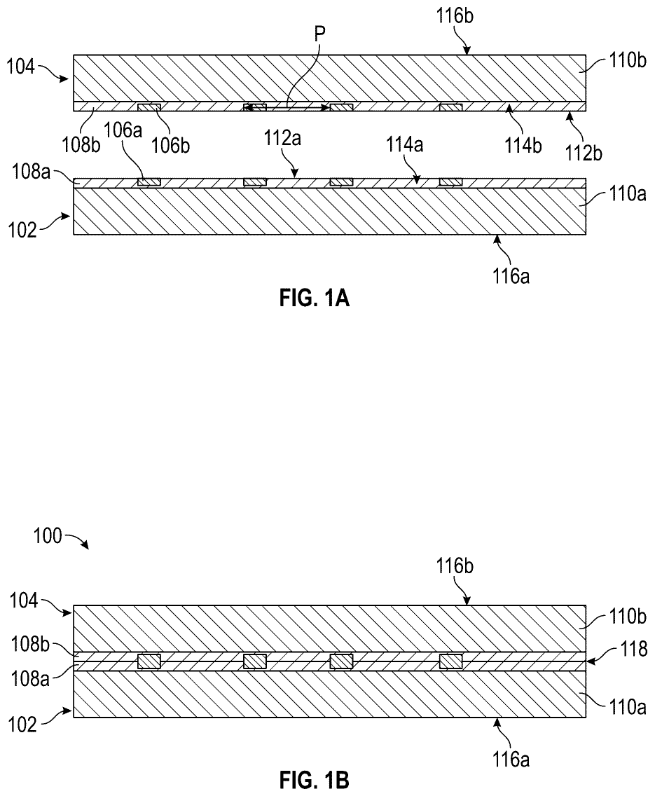

FIGS. 1A and 1B schematically illustrate cross-sectional side views of two elements 102, 104 prior to and after, respectively, a process for forming a directly bonded structure, and more particularly a hybrid bonded structure 100 without an intervening adhesive according to some embodiments. Hybrid bonding is a species of direct bonding in which both nonconductive features directly bond to nonconductive features, and conductive features directly bond to conductive features. In FIGS. 1A and 1B, a bonded structure 100 comprises two elements 102 and 104 that can be directly bonded to one another at a bond interface 118 without an intervening adhesive. Two or more microelectronic elements 102 and 104 (such as semiconductor elements, including, for example, integrated device dies, wafers, passive devices, individual active devices such as power switches, etc.) may be stacked on or bonded to one another to form the bonded structure 100. Conductive features 106a (e.g., contact pads, traces, electrodes, exposed ends of vias or through substrate vias (TSVs)) of a first element 102 may be electrically connected to corresponding conductive features 106b of a second element 104. As explained below, in other implementations, the elements 102 and/or 104 may not include conductive features at the bond interface 118. Any suitable number of elements can be stacked in the bonded structure 100. For example, a third element (not shown) can be stacked on the second element 104, a fourth element (not shown) can be stacked on the third element, and so forth. In such implementations, TSVs can be formed to provide vertical electrical communication between and/or among the vertically-stacked elements. Additionally or alternatively, one or more additional elements (not shown) can be stacked laterally adjacent one another along the first element 102. In some embodiments, a laterally stacked additional element may be smaller than the second element. In some embodiments, the laterally stacked additional element may be two times smaller than the second element.

In some embodiments, the elements 102 and 104 are directly bonded to one another without an adhesive using a suitable direct bonding process. In various embodiments, a non-conductive field region that includes a non-conductive or dielectric material can serve as a first bonding layer 108a of the first element 102 which can be directly bonded to a corresponding non-conductive field region that includes a non-conductive or dielectric material serving as a second bonding layer 108b of the second element 104 without an adhesive. The non-conductive bonding layers 108a and 108b can be disposed on respective front sides 114a and 114b of base substrate portions 110a and 110b. In some embodiments, the base substrate portion can comprise a device portion, such as a bulk semiconductor (e.g., silicon) portion of the elements 102, 103, and back-end-of-line (BEOL) interconnect layers over such semiconductor portions. Active devices and/or circuitry can be patterned and/or otherwise disposed in or on the base substrate portions 110a and 110b. Active devices and/or circuitry can be disposed at or near the front sides 114a and 114b of the base substrate portions 110a and 110b, and/or at or near opposite backsides 116a and 116b of the base substrate portions 110a and 110b. In other embodiments, the base substrate portions 110a, 110b may not include active circuitry, but may instead comprise dummy substrates, passive interposers, passive optical elements (e.g., glass substrates, gratings, lenses), etc. Bonding layers can be provided on front sides and/or back sides of the elements. The non-conductive material can be referred to as a non-conductive bonding region or bonding layer 108a of the first element 102. In some embodiments, the non-conductive bonding layer 108a of the first element 102 can be directly bonded to the corresponding non-conductive bonding layer 108b of the second element 104 using dielectric-to-dielectric bonding techniques.

To effectuate direct bonding between the bonding layers 108a, 108b, the bonding layers 108a, 108b can be polished to a high degree of smoothness (e.g., by chemical-mechanical polishing, or CMP), activated with a suitable species, and bonded to one another at room temperature, without the need for application of a voltage, and without the need for application of external pressure or force beyond that used to initiate contact between the two elements 102, 104. The nonconductive bonding surfaces 112a and 112b can be polished using, for example, chemical mechanical polishing (CMP). The roughness of the polished bonding surfaces 112a and 112b can be less than 30 Å rms. For example, the roughness of the bonding surfaces 112a and 112b can be in a range of about 0.1 Å rms to 15 Å rms, 0.5 Å rms to 10 Å rms, or 1 Å rms to 5 Å rms.

The bonding surfaces 112a and 112b can be cleaned and exposed to a plasma and/or etchants to activate the surfaces 112a and 112b. In some embodiments, the surfaces 112a and 112b can be terminated with a species after activation or during activation (e.g., during the plasma and/or etch processes). Without being limited by theory, in some embodiments, the activation process can be performed to break chemical bonds at the bonding surfaces 112a and 112b, and the termination process can provide additional chemical species at the bonding surfaces 112a and 112b that alters the chemical bond and/or improves the bonding energy during direct bonding. In some embodiments, the activation and termination are provided in the same step, e.g., a plasma to activate and terminate the surfaces 112a and 112b. In other embodiments, the bonding surfaces 112a and 112b can be terminated in a separate treatment to provide the additional species for direct bonding. In various embodiments, the terminating species can comprise nitrogen. For example, in some embodiments, the bonding surface(s) 112a, 112b can be exposed to a nitrogen-containing plasma. Further, in some embodiments, the bonding surfaces 112a and 112b can be exposed to fluorine. For example, there may be one or multiple fluorine concentration peaks at or near a bond interface 118 between the first and second elements 102, 104. Typically, fluorine concentration peaks occur at interfaces between material layers.

Thus, in the directly bonded structure 100, the bond interface 118 between two non-conductive materials (e.g., the bonding layers 108a and 108b) can comprise a very smooth interface with higher nitrogen content and/or fluorine concentration peaks at the bond interface 118. Additional examples of activation and/or termination treatments may be found throughout U.S. Pat. Nos. 9,564,414; 9,391,143; and 10,434,749, the entire contents of each of which are incorporated by reference herein in their entirety and for all purposes. The roughness of the polished bonding surfaces 112a and 112b can be slightly rougher (e.g., about 1 Å rms to 30 Å rms, 3 Å rms to 20 Å rms, or possibly rougher) after an activation process. Accordingly, non-conductive or dielectric-to-dielectric bonds may be formed without an adhesive using the direct bonding techniques disclosed at least in U.S. Pat. Nos. 9,564,414; 9,391,143; and 10,434,749.

In various embodiments, the bonding layers 108a and/or 108b can comprise a non-conductive material such as a dielectric material, such as silicon oxide, or an undoped semiconductor material, such as undoped silicon. Suitable dielectric bonding surface or materials for direct bonding include but are not limited to inorganic dielectrics including silicon, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In some embodiments, at least one of the elements to be bonded can comprise an organic or ceramic substrate (e.g., as the base substrate portion 110a, 110b of the element). In such embodiments, for example, an inorganic bonding layer can be deposited on a first element including the organic or ceramic substrate (e.g., a package substrate including one or more organic or ceramic materials). A second element can be directly bonded to the inorganic bonding layer without an adhesive. Additional details regarding direct bonding to organic or ceramic substrates may be found throughout (and including at least, e.g., ¶¶ [0016]-[0026] and [0038]-[0039] of) U.S. patent application Ser. No. 18/145,607, filed Dec. 22, 2022, the entire contents of which are incorporated by reference herein in their entirety and for all purposes.

In other embodiments, the bonding layers 108a and/or 108b can comprise an electrically conductive material, such as a deposited conductive oxide material, e.g., indium tin oxide (ITO). Additional examples of directly bonded structures utilizing conductive oxide materials can be found throughout U.S. Provisional Patent Application No. 63/524,564, filed Jun. 30, 2023, the entire contents of which is incorporated by reference herein in its entirety and for all purposes.

Embodiments described herein are particularly useful for reducing thermal budget consumption for direct hybrid bonding. For example, in some embodiments, the base substrate portions 110a and 110b can have significantly different coefficients of thermal expansion (CTEs) defining a heterogenous structure. The CTE difference between the base substrate portions 110a and 110b, and particularly between bulk semiconductor, typically single crystal portions of the base substrate portions 110a, 110b, can be greater than 5 ppm or greater than 10 ppm. For example, the CTE difference between the base substrate portions 110a and 110b can be in a range of 5 ppm to 100 ppm, 5 ppm to 40 ppm, 10 ppm to 100 ppm, or 10 ppm to 40 ppm.

In some embodiments, one of the base substrate portions 110a and 110b can comprise optoelectronic single crystal materials, including perovskite materials, that are useful for optical piezoelectric or pyroelectric applications, and the other of the base substrate portions 110a, 110b comprises a more conventional substrate material. For example, one of the base substrate portions 110a, 110b comprises lithium tantalate (LiTaO3) or lithium niobate (LiNbO3), and the other one of the base substrate portions 110a, 110b comprises silicon (Si), quartz, fused silica glass, sapphire, or a glass. In other embodiments, one of the base substrate portions 110a and 110b comprises a III-V single semiconductor material, such as gallium arsenide (GaAs) or gallium nitride (GaN), and the other one of the base substrate portions 110a and 110b can comprise a non-III-V semiconductor material, such as silicon (Si), or can comprise other materials with similar CTE, such as quartz, fused silica glass, sapphire, or a glass. It can be challenging to form a reliable bonding between such heterogenous substrates, and the stress from the CTE difference calls for a lower thermal budget during the annealing process. Various rapid thermal processes disclosed herein can enable such lower thermal budgets for annealing for direct hybrid bonded. The skilled artisan will appreciate that lowering thermal budgets for annealing can be advantageous for a number of other types of direct bonding as well.

In some implementations (not illustrated), each bonding layer has one material. The materials of opposing bonding layers on the different elements can be the same or different, and may comprise elemental or compound materials. In such implementations, the bonding layers can be patterned, or can be unpatterned such that the bonding surface of each element includes a blanket deposited material. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across the surface(s) of the elements (or across the surface of the smaller element if the elements are differently-sized). For such directly bonded nonconductive bonding layers, it may be that only nonconductive materials are bonded to one another (e.g., there are no conductive direct bonds between the elements). Such direct bonding processes may be referred to as “uniform” direct bond to signify that only one material on each element is directly bonded. Example uniform direct bonding processes include the ZIBOND® techniques commercially available from Adeia of San Jose, CA. In such uniform direct bonding processes, one or both of the nonconductive bonding layers may be without any conductive features patterned therein. Alternatively, one or both of the nonconductive bonding layers may include one or more conductive features, but the conductive features are not involved in the bonding. An alternative example of uniform direct bonding processes can include electrically conductive material(s), such as deposited conductive oxides, as disclosed in U.S. Provisional Patent Application No. 63/524,564, filed Jun. 30, 2023, the entire contents of which are incorporated by reference in their entirety and for all purposes.

In various embodiments, hybrid bonds can be formed without an intervening adhesive. Most commonly, hybrid bonds involve opposing nonconductive surfaces that are directly bonded without an intervening adhesive and opposing conductive features that are directly bonded without an intervening adhesive. For example, as explained above, nonconductive bonding surfaces 112a and 112b can be prepared for direct bonding, such as by polishing to a high degree of smoothness, activating and/or terminating with a suitable species, and bringing into contact with one another (for example, at room temperature and without application of pressure beyond that used to bring the elements 102, 104 into contact). In hybrid bonding, conductive features 106a of the first element 102 can also be directly bonded to corresponding conductive features 106b of the second element 104 without an adhesive (e.g., without solder or other conductive adhesive intervening between the conductive features 106a, 106b). For example, a direct hybrid bonding technique can be used to provide conductor-to-conductor direct bonds along the bond interface 118 that includes covalently direct bonded non-conductive-to-non-conductive (e.g., dielectric-to-dielectric) surfaces, prepared as described above. In various embodiments, the conductor-to-conductor (e.g., conductive feature 106a to conductive feature 106b) direct bonds and the dielectric-to-dielectric direct bonds can be formed using the hybrid bonding techniques disclosed at least in U.S. Pat. No. 9,716,033, the entire contents of which are incorporated by reference herein in their entirety and for all purposes. In hybrid bonding embodiments described herein, conductive features are provided within non-conductive bonding layers, and both conductive and nonconductive features are prepared for direct bonding, such as by the planarization, activation and/or termination treatments described above. Thus, the bonding surface prepared for hybrid bonding includes both conductive and non-conductive features.

For example, non-conductive (e.g., dielectric) bonding surfaces 112a, 112b (for example, inorganic dielectric surfaces) can be prepared and directly bonded to one another without an intervening adhesive as explained above. Conductive contact features (e.g., conductive features 106a and 106b which may be at least partially surrounded by non-conductive dielectric field regions within the bonding layers 108a, 108b) may also directly bond to one another without an intervening adhesive. In various embodiments, the conductive features 106a, 106b can comprise discrete pads or traces at least partially embedded in the non-conductive field regions. In some embodiments, the conductive contact features can comprise exposed contact surfaces of through substrate vias (e.g., through silicon vias (TSVs)).

In some embodiments, prior to direct bonding portions of the respective conductive features 106a and 106b can be recessed below exterior (e.g., upper) surfaces (non-conductive bonding surfaces 112a and 112b) of the dielectric field region or non-conductive bonding layers 108a and 108b, for example, recessed by less than 30 nm, less than 20 nm, less than 15 nm, or less than 10 nm, for example, recessed in a range of 2 nm to 20 nm, or in a range of 4 nm to 10 nm. The recess can be at or near the middle or center of the cavity in which the conductive features 106a, 106b are disposed, and, additionally or alternatively, can extend or be disposed along sides of the cavity in which the conductive features 106a, 106b are disposed. In various embodiments, prior to direct bonding, the recesses in the opposing elements can be sized such that the total gap between opposing contact pads is less than 15 nm, or less than 10 nm.

The non-conductive bonding layers 108a and 108b can be directly bonded to one another without an adhesive at room temperature in some embodiments and, subsequently, the bonded structure 100 can be annealed. Upon annealing, the conductive features 106a and 106b can expand and contact one another to form a metal-to-metal direct bond. Beneficially, the use of Direct Bond Interconnect, or DBI®, techniques commercially available from Adeia of San Jose, CA, can enable high density of conductive features 106a and 106b to be connected across the direct bond interface 118 (e.g., small or fine pitches for regular arrays).

In some embodiments, a pitch p of the conductive features 106a and 106b, such as conductive traces embedded in the bonding surface of one of the bonded elements, may be less than 100 μm, less than 10 μm, less than 2 μm, or even less than 1 μm. For some applications, the ratio of the pitch of the conductive features 106a and 106b to one of the dimensions (e.g., a diameter) of the bonding pad is less than is less than 20, or less than 10, or less than 5, or less than 3 and sometimes desirably less than 2. In other applications, the width of the conductive traces embedded in the bonding surface of one of the bonded elements may range between 0.3 μm to 50 μm, e.g., in a range of 0.3 μm to 20 μm, 0.3 μm to 3 μm, 0.5 μm to 50 μm, 0.75 μm to 25 μm, or 1 μm to 5 μm. In various embodiments, the conductive features 106a and 106b and/or traces can comprise copper or copper alloys, although other metals may be suitable. For example, the conductive features disclosed herein, such as the conductive features 106a and 106b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

Thus, in direct bonding processes, a first element 102 can be directly bonded to a second element 104 without an intervening adhesive. In some arrangements, the first element 102 can comprise a singulated element, such as a singulated integrated device die. In other arrangements, the first element 102 can comprise a carrier or substrate (e.g., a wafer) that includes a plurality (e.g., tens, hundreds, or more) of device regions that, when singulated, form a plurality of integrated device dies. Similarly, the second element 104 can comprise a singulated element, such as a singulated integrated device die. In other arrangements, the second element 104 can comprise a carrier or substrate (e.g., a wafer). The embodiments disclosed herein can accordingly apply to wafer-to-wafer (W2W), die-to-die (D2D), or die-to-wafer (D2W) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding interfaces for both bonded and singulated elements can be coextensive, and may include markings indicative of the common singulation process for the bonded structure (e.g., saw markings if a saw singulation process is used).

As explained herein, the first and second elements 102 and 104 can be directly bonded to one another without an adhesive, which is different from a deposition process and results in a structurally different interface compared to a deposition. In one application, a width of the first element 102 in the bonded structure is similar to a width of the second element 104. In some other embodiments, a width of the first element 102 in the bonded structure 100 is different from a width of the second element 104. Similarly, the width or area of the larger element in the bonded structure may be at least 10% larger than the width or area of the smaller element. The first and second elements 102 and 104 can accordingly comprise non-deposited elements. Further, directly bonded structures 100, unlike deposited layers, can include a defect region along the bond interface 118 in which nanometer-scale voids (nanovoids) are present. The nanovoids may be formed due to activation of the bonding surfaces 112a and 112b (e.g., exposure to a plasma).

As explained above, the bond interface 118 can include concentration of materials from the activation and/or last chemical treatment processes. For example, in embodiments that utilize a nitrogen plasma for activation, a nitrogen concentration peak can be formed at the bond interface 118. The nitrogen concentration peak can be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH2 molecules, yielding a nitrogen-terminated surface. In embodiments that utilize an oxygen plasma for activation, an oxygen concentration peak can be formed at the bond interface 118. In some embodiments, the bond interface 118 can comprise silicon oxynitride, silicon oxycarbonitride, or silicon carbonitride. As explained herein, the direct bond can comprise a covalent bond, which is stronger than van Der Waals bonds. The bonding layers 108a and 108b can also comprise polished surfaces that are planarized to a high degree of smoothness.

For hybrid bonded elements 102, 104, as shown, the orientations of one or more conductive features 106a, 106b from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductive features'sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 106b in the bonding layer 108b (and/or at least one internal conductive feature, such as a BEOL feature) of the upper element 104 may be tapered or narrowed upwardly, away from the bonding surface 112b. By way of contrast, at least one conductive feature 106a in the bonding layer 108a (and/or at least one internal conductive feature, such as a BEOL feature) of the lower element 102 may be tapered or narrowed downwardly, away from the bonding surface 112a. Similarly, any bonding layers (not shown) on the backsides 116a, 116b of the elements 102, 104 may taper or narrow away from the backsides, with an opposite taper orientation relative to front side conductive features 106a, 106b of the same element.

As described above, the non-conductive bonding layers 108a, 108b can be directly bonded to one another without an adhesive and, subsequently, the bonded structure 100 can be annealed. Upon annealing, the conductive features 106a, 106b can expand and contact one another to form a metal-to-metal direct bond. In some embodiments, the materials of the conductive features 106a, 106b can interdiffuse during the annealing process. In various embodiments, the metal-to-metal bonds between the conductive features 106a and 106b can be joined such that metal grains grow into each other across the bond interface 118. In some embodiments, the metal is or includes copper, which can have grains oriented along the 111 crystal plane for improved copper diffusion across the bond interface 118. In some embodiments, the conductive features 106a and 106b may include nanotwinned copper grain structure, which can aid in merging the conductive features during anneal. The bond interface 118 can extend substantially entirely to at least a portion of the bonded conductive features 106a and 106b, such that there is substantially no gap between the non-conductive bonding layers 108a and 108b at or near the bonded conductive features 106a and 106b. In some embodiments, a barrier layer may be provided under and/or laterally surrounding the conductive features 106a and 106b (e.g., which may include copper). In other embodiments, however, there may be no barrier layer under the conductive features 106a and 106b, for example, as described in U.S. Pat. No. 11,195,748, which is incorporated by reference herein in its entirety and for all purposes.

As described herein, in direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some nonconductive adhesive-based processes, a flowable adhesive (e.g., an organic adhesive, such as an epoxy) can be applied to one or both elements and cured to form the physical connection between elements. In such nonconductive adhesive processes, the adhesive does not form a strong chemical bond with either element. In other processes, a conductive adhesive (e.g., solder) can be provided between the two elements, heated to melt the conductive adhesive, and cooled to form the connection between the two elements. In both nonconductive and conductive adhesive processes, the resulting attachment of the two adhered elements results from an intervening material that sticks or adheres to the two opposing elements to be joined. The connection is primarily a physical connection between the two elements, and does not involve the formation of covalent bonds or grain growth across the elements.

By contrast, direct bonding processes join two elements by forming strong chemical bonds (e.g., covalent bonds) between opposing nonconductive materials and/or by causing grain growth across the bonding interface between opposing conductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds can be strengthened after annealing the elements (e.g., for opposing conductive oxide structures, such as opposing ITO layers).

In hybrid bonding processes the interface includes conductive direct bonds and the conductive material (e.g., metallic material) typically expands upon annealing, but the direct bonds between surrounding nonconductive materials resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in direct bonding processes that include conductive direct bonds, opposing conductive materials are joined without melting the conductive materials, such that bonds can form with much lower anneal temperatures compared to adhesive-based processes, such as soldering, where the conductive materials are heated above the melting temperature.

Various embodiments disclosed herein relate to using a rapid thermal process (RTP) to anneal the bonded structure 100. The RTP uses radiant energy sources to heat the bonded structure 100. The RTP can enable the bonded structure 100 to be heated to a target temperature, such as a temperature in a range of 250 °C to 500 °C, very quickly compared to conventional convection oven annealing (e.g., less than 10 seconds, 7 seconds, 5 seconds, or 3 seconds). The RTP can more quickly heat the bonded structure 100 than other types of heating process, such as convection heating and conductive heating processes. Although RTP has been employed for annealing in a number of other contexts, it has been challenging to obtain temperature uniformity across substrates due to the nature of rapid radiant heating.

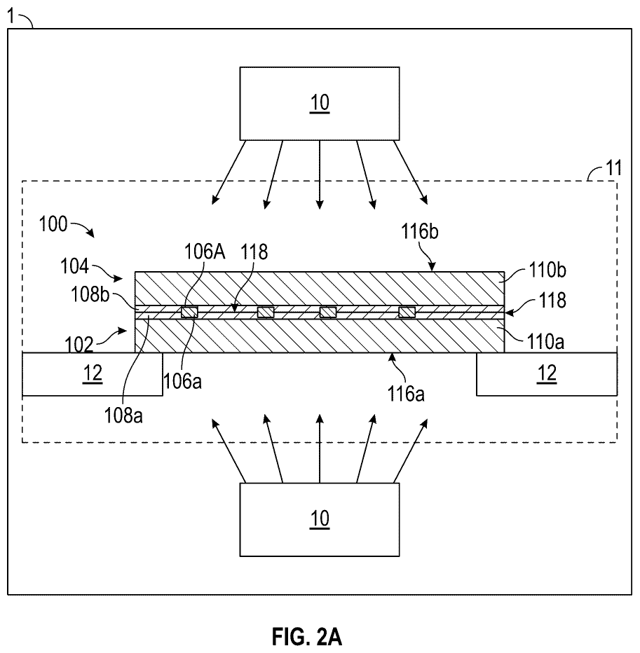

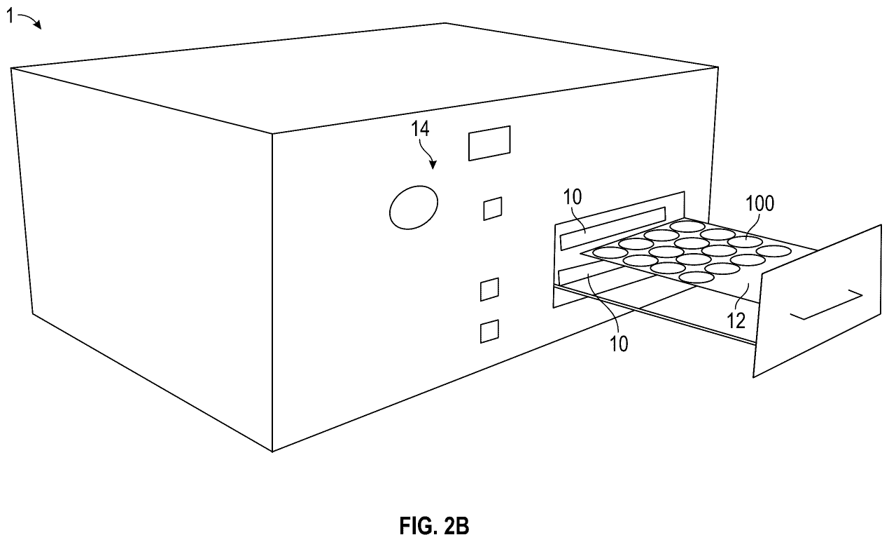

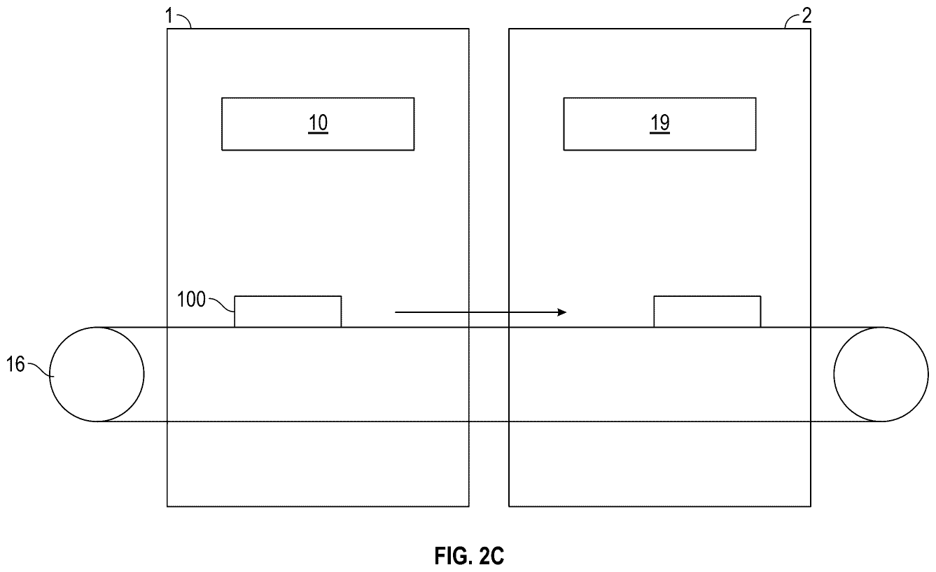

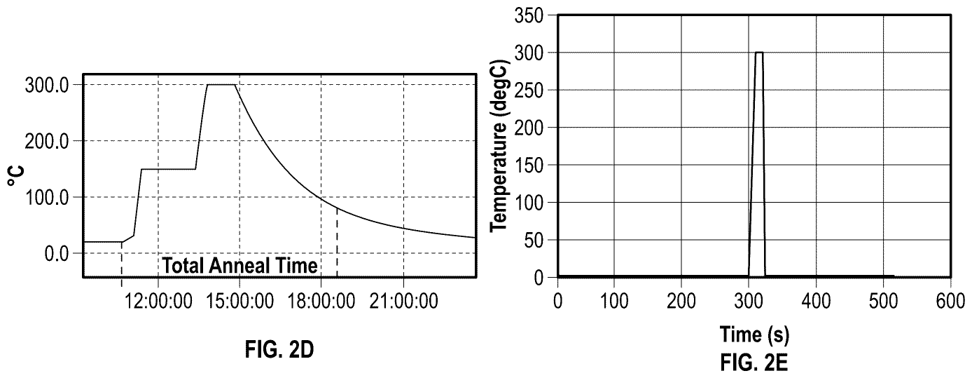

FIG. 2A is a schematic cross section of a bonded structure 100 within an RTP system 1. In the illustrated example, the RTP system 1 includes a single-substrate RTP chamber 11. As shown, the bonded structure 100 is supported by a support structure 12 (e.g., susceptor, support fingers or brackets, or a support ring) in the chamber 11 in a manner that allows exposure to radiant heat (illustrated by arrows) from radiant energy sources 10, such as heat lamps. Typically the radiant energy sources 10 are positioned outside the chamber 11 and the chamber walls are transparent to wavelengths of light that accomplish the heating of the bonded structure 100. Similarly, the support structure 12 can be transparent to wavelengths of light that accomplish the heating of the bonded structure 100. The radiant energy sources 10 can be provided on one side of the bonded structure 100, two opposite sides of the bonded structure 100 as shown, or on multiple additional sides of the bonded structure 100. Radiant heat energy can be provided directly to the bonded structure 100 as shown, or by way of a radiant heat absorbent susceptor that extends under the bonded structure 100. Lamps or laser sources can be used as the radiant energy sources 10. The lamps can include, for example, gas-fillet tungsten filament lamps (e.g., infrared halogen lamps). For example, the lamps can emit radiation that has a wavelength in a visible to microwave range or a visible to infrared range. The RTP system 1 typically includes temperature sensors to estimate the substrate (bonded structure 100) temperature and provide feedback to temperature control systems that instruct the heating process.

FIG. 2B is a schematic perspective view of another example RTP system 1 that can be used to anneal multiple bonded structures 100 simultaneously. The RTP system 1 can include one or more radiant energy sources 10, a support structure 12 (e.g., tray or plate as part of or placeable on a drawer) for placing the bonded structure(s) 100, and a user interface 14 that includes switches for controlling the RTP system 1 and indicators for indicating the state of the RTP system 1. The radiant heat sources 10 can be lamps or laser sources as described above. In the illustrated embodiment, multiple bonded structure(s) 100 can be inserted into the RTP system 1 and heated by the radiation from the radiant energy sources 10. AccuThermo AW 810 RTP manufactured by Allwin 21 Corp. is an example of the RTP system 1.

FIG. 2C is a schematic view of a heating system. The heating system of FIG. 2C can comprise a belt furnace that includes a conveyor 16 (e.g., a belt conveyor) that carries substrate through the RTP heating system 1. The RTP heating system 1 can include the radiant energy source 10. The conveyor 16 can feed the bonded structure 100 through the RTP system 1.

Various embodiments disclosed herein can utilize two or more heating mechanisms for heating a bonded structure. For example, the bonded structure can be heated by way of the RTP and a non-RTP heating process such as a convection or conduction heating that does not use radiant energy for heating the bonded structure. In some embodiments, the bonded structure can be heated by way of the RTP, and separately heated by the non-RTP heating process in a separate anneal tool.

In some embodiments, an anneal system can include both an RTP zone (such as the illustrated RTP system 1), as well as a non-RTP heating system 2 having a second heating source 19, as shown in FIG. 2C. For example, an anneal process can include both RTP anneal and non-RTP anneal (e.g., convection heating), as will be understood from the process descriptions below. As shown in FIG. 2C, both anneal phases can be conducted in one tool, such as a conveyor belt tool having different types of heating in different zones, such as a radiative heating zone defined by the RTP heating system 1, and a convectively or conductively heated zone defined by the non-RTP system 2. This may allow the bonded structure to be heated by the RTP and the non-RTP heating process in a continuous process. Accordingly, a system can include both the RTP heating system 1 and the non-RTP heading system 2. In FIG. 2C, the annealing apparatus can include a system for conveyance of the bonded structure 100 between the RTP heading system 1 and the non-RTP heating system. The conveyance of FIG. 2C comprises the conveyor 16 that allows for a continuous process for multiple anneal phases through different heating zones.

FIG. 2D is a graph showing an annealing profile of a typical convection anneal process with different stages. FIG. 2E is a graph showing an annealing profile of an anneal process using the RTP. The convection anneal process can include a first, low temperature anneal at about 150 °C for about two hours followed by a second, high temperature anneal at about 300 °C for about an hour. The total anneal time of the convection anneal process illustrated in FIG. 2D is about 7.5 hours. The RTP anneal process can include an anneal at the peak temperature of about 300 °C for about 10 seconds. The RTP anneal process has a ramp rate of about 25 °C per second.

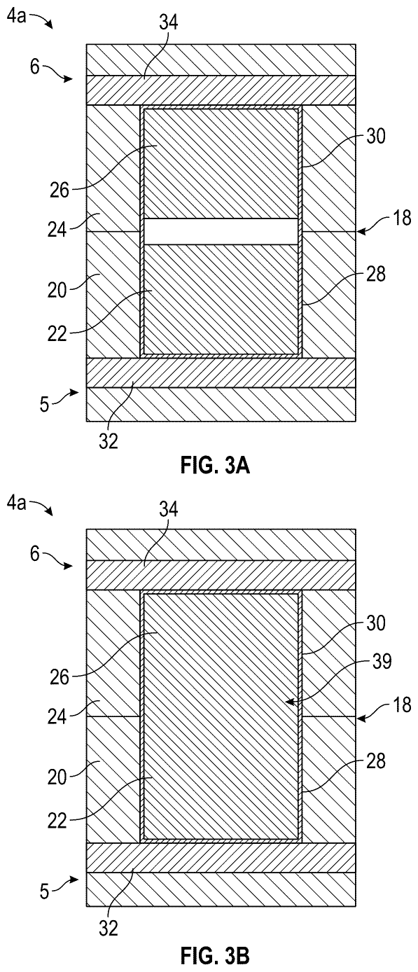

FIGS. 3A-3B show a process of annealing a bonded structure 4a according to an embodiment. The illustrated bonded structure 4a-4d can be a portion of a larger structure. For example, the larger structure can include substrate portions (e.g., the device portions 110a, 110b, including bulk single crystal portions, described above with respect to FIGS. 1A and 1B). Unless otherwise noted, components of FIGS. 3A-3B can be the same as or generally similar to like components shown in FIGS. 1A and 1B.

FIG. 3A is a schematic cross-sectional side view of the bonded structure 4a prior to annealing. The bonded structure 4a can include a first element 5 that includes a first non-conductive field region 20 and a first conductive feature 22, and a second element 6 that includes a second non-conductive field region 24 and a second conductive feature 26. In some embodiments, the first element 5 can include a first barrier layer 28 at least partially between the first non-conductive field region 20 and the first conductive feature 22, and the second element 6 can include a second barrier layer 30 at least partially between the second non-conductive field region 24 and the second conductive feature 26. The barriers (the first barrier 28 and the second barrier 30) can be formed of various materials (such as metal nitrides, carbides, silicides, etc.) and are useful in preventing or inhibiting metal (such as copper) of the conductive features from diffusing into the surrounding non-conductive materials. In some embodiments, the first and second elements 5, 6 can also include back end of line layers 32, 34, shown schematically to represent multiple metallization layers between the bonding layer (including non-conductive field regions 20, 24 and conductive features 22, 26 on each element 5, 6) and devices, which can be formed on or in bulk semiconductor materials. The bulk semiconductor materials can correspond to the substrate or device portions (e.g., the device portions 110a, 110b described above with respect to FIGS. 1A and 1B) which can define a majority of the elements 5, 6.

The first non-conductive field region 20 of the first element 5 is directly bonded to the second non-conductive field region 24 without an intervening adhesive along a bond interface 18. Surfaces of the first non-conductive field region 20 and the second non-conductive field region 24 can be prepared for direct bonding prior to contacting the first and second elements 5, 6, as described herein. For example, one or both of the surfaces of the first and second elements 5, 6 can be polished to have a surface roughness of less than 15 Å rms, less than 10 Å rms, or less than 5 Å rms. For example, the one or both of the surfaces of the first and second elements 5, 6 can have a surface roughness in a range of 1 Å rms to 15 Å rms, 1 Å rms to 10 Å rms, or 1 Å rms to 5 Å rms. As noted above, the direct bond between non-conductive materials of the two elements can be formed at room temperature, and can include formation of covalent bonds.

The conductive features 22, 26 can be recessed below respective bonding surfaces of the non-conductive field region 20, 24. For example, the conductive features 22, 26 can be recessed by less than 30 nm, less than 20 nm, less than 15 nm, or less than 10 nm, for example, recessed in a range of 2 nm to 20 nm, or in a range of 4 nm to 10 nm, relative to the respective bonding surfaces of the non-conductive field region 20, 24. In some embodiments, the recesses in the opposing elements 5, 6 can be sized such that the total gap between opposing conductive features 22, 26 is less than 15 nm, or less than 10 nm after the room temperature bonding of non-conductive materials and prior to annealing.

The first and second conductive features 22, 26 can comprise any suitable conductive material. In some embodiments, the first and second conductive features 22, 26 can comprise metal, such as copper. For example, the first and second conductive features 22, 26 can comprise a fine grain metal (e.g., fine grain copper). The fine grain metal can be defined as a metal having an average grain width less than 20 nm, less than 50 nm, less than 100 nm, less than 300 nm, or less than 500 nm. For example, the maximum width of grain in the fine grain metal can be in a range of 10 nm to 500 nm, 20 nm to 500 nm, or 100 nm to 300 nm. Various benefits of using the RTP disclosed herein may be pronounced when a fine grain metal is used as the first and/or second conductive features 22, 26 as compared to using larger grain metals. Additional details of fine grain metals may be found throughout U.S. patent application Ser. Nos. 17/684,841, 18/066,159, and 18/305,149, the entire contents of each of which are incorporated by reference herein in their entirety and for all purposes.

FIG. 3B illustrates the bonded structure 4a of FIG. 3A after annealing, including rapid thermal processing, to expand and merge conductive features 22, 26 of opposite elements 5, 6 and form a directly bonded conductive feature 39. Surprisingly, rapid thermal processing was found to reliably form electrical connections between aligned and recessed conductive features even for multiple such features distributed over large substrates. Die to wafer (D 2W) bonding experiments were conducted with a die size of 128 mm² (8 mm×16 mm). Between a die and the wafer, there are 31,356 daisy chain links, such that current can only flow if all the die contacts are electrically connected across the bond interface, each contact being about 10 μm in diameter with a pitch of about 40 μm. The experiments were conducted under nitrogen ambient to prevent or mitigate oxidation of the exposed pads for probing the interconnect array. All of the contacts were found to have electrical connection after room temperature bonding and annealing in an RTP system.

The RTP can quickly increase the temperature of the bonded structure 4a such that the first and second conductive features 22, 26 expand to make contact with one another. For example, the RTP can bring the temperature of the bonded structure 4a to a target temperature, such as a temperature in a range of 250 °C to 500 °C, in, for example, less than 10 seconds, 7 seconds, 5 seconds, or 3 seconds. In some embodiments, due to the material characteristics of the non-conductive portion (the first and second non-conductive field region 20, 24) and the conductive portion (the first and second conductive features 22, 26), the radiation used in the RTP can raise the temperature of the conductive portion more quickly than the non-conductive portion. For example, silicon and dielectric materials conventionally used to form microelectronic elements, such as integrated circuits, tend to be more transparent to wavelengths used in RTP tools as compared to conductive materials like metals. This can cause problems in some contexts, since the temperature of the overall substrate or element can be measured but may not reflect the actual temperature of more absorbent conductive materials. Nevertheless, the non-uniform absorption of radiant heat can be beneficial for annealing in the direct hybrid bonding context. Because the temperature of the conductive portion can be raised more quickly than the non-conductive portion, the conductive portion can be heated to a higher temperature than the non-conductive portion at a given time. Conventional hybrid bonding anneals rely on differences in coefficients of thermal expansion (CTE) between the conductive materials and their surrounding non-conductive materials to achieve differential expansion of the conductive materials into contact. However, in the present disclosure, radiant heat aids thermal expansion of the conductive materials by providing differential temperatures in addition to differential CTE. Both temperature differentials and CTE differentials contribute to differential expansion of the conductive materials relative to the surrounding non-conductive materials, which can enable a reliable bond between the first and second conductive features 22, 26 at lower temperatures and/or lower anneal times compared to conventional annealing.

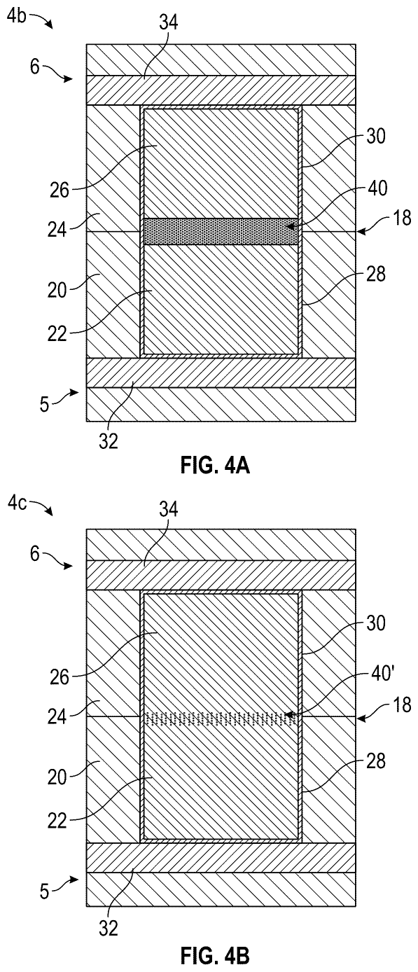

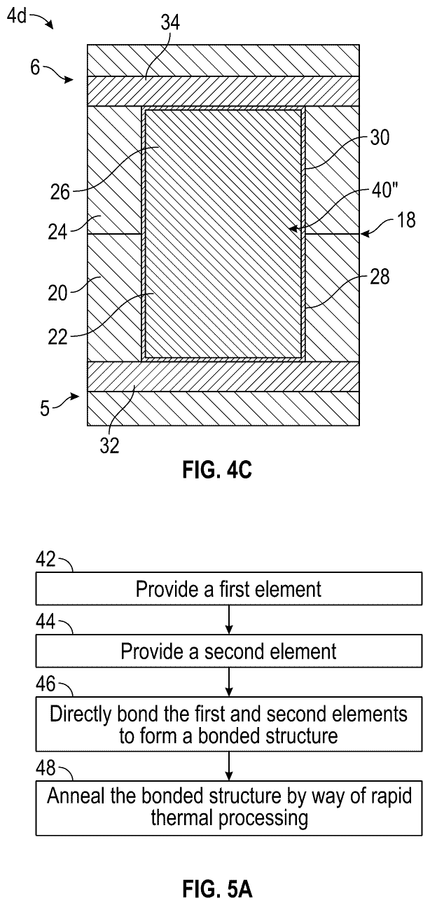

The anneal may include multiple phases, of which one or more phases are rapid thermal anneals. For example, FIG. 4A is a schematic cross-sectional side view of the bonded structure 4b after a first annealing process. The first annealing process can include a rapid thermal process (RTP). The bonded structure 4a shown in FIG. 3A can be annealed to form the bonded structure 4b. In the bonded structure 4b, the first and second conductive features 22, 26 are directly bonded and electrically connected to one another. In some embodiments, the first annealing process can form an initial contact between the first and second conductive features 22, 26.

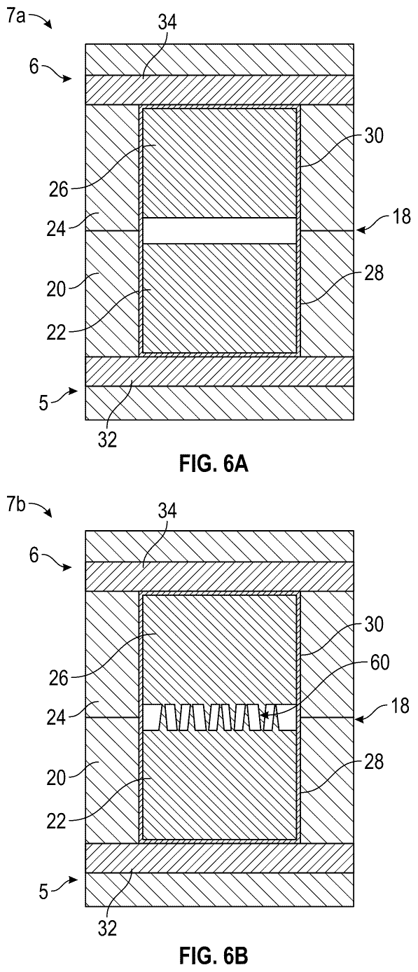

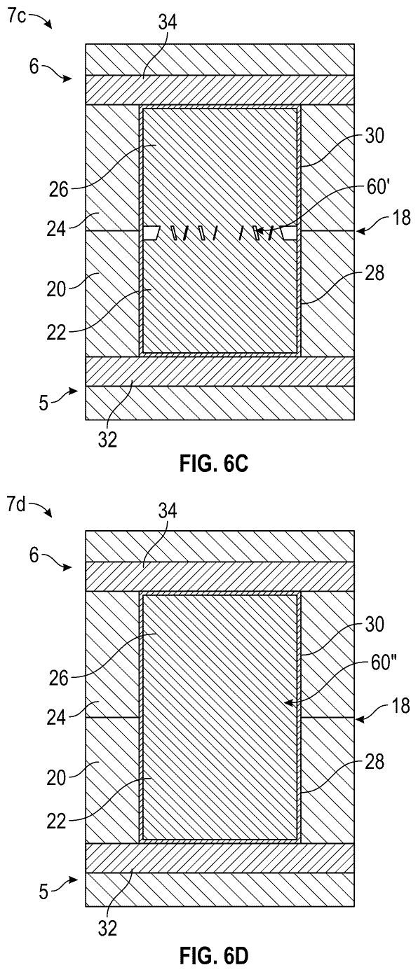

As a result of the first annealing process, the bonded structure 4b can include a rapid growth structure 40 characteristic of an RTP anneal. In some embodiments, the rapid growth structure 40 can be different from a result of a non-RTP heating process. For example, the rapid growth structure 40 can comprise grain configurations traversing the bond interface 18 (see FIGS. 6A-6D) that are different from the grain configurations in a bonded structure that has been annealed using only the non-RTP heating process.

In the bonded structure 4b, interdiffusion between the bonded first and second conductive features 22, 26 may take place. However, in some embodiments, a majority of the interdiffusion between the bonded first and second conductive features 22, 26 can take place in a second annealing process (see FIG. 4B). As described above with respect to FIG. 3B, if RTP alone is used for annealing the bonded structure, the RTP may be prolonged and/or at a higher peak temperature to accomplish sufficient interdiffusion for the final product. The RTP can initiate contact across the gap at an early stage, typically multiple connections per a conductive feature pair, and those connections can serve to accelerate interdiffusion in a subsequent non-RTP anneal, which can significantly reduce overall annealing time.

In the embodiment of FIGS. 4A-4C, however, additional anneal phases can be included. FIG. 4B is a schematic cross-sectional side view of the bonded structure 4c after a second annealing process. The second annealing process can include a rapid thermal process (RTP) and/or a non-RTP heating process. For example, the second annealing process can include the non-RTP heating process for a duration that is longer than a duration of the first annealing process, and/or another RTP phase. In the bonded structure 4c, the electrical connection between the first and second conductive features 22, 26 can be stronger, more reliable, and/or more durable than the bonded structure 4b. In some embodiments, during the second annealing process, the first and second conductive features 22, 26 can grow and interdiffuse to a greater degree, to form a larger bond interface for the conductive materials and larger grains compared to the RTP anneal phase alone.

After the second annealing process, at least a portion of the rapid growth structure 40 can remain as a rapid growth structure 40'. In other words, some of the grain configurations characteristic of RTP anneal can remain near the bond interface 18 of the conductive features 22, 26. In some embodiments, the rapid growth structure 40′ can include a stress gradient and/or a gradient of interdiffused metal atoms. In some embodiments, the bonded structure 4c can be the final structure and the following step(s) (FIG. 4C) may be omitted.

FIG. 4C is a schematic cross-sectional side view of the bonded structure 4d after a third annealing process. In some embodiments, the third annealing process can be a continuation of the second annealing process. In some other embodiments, the third annealing process can include a separate annealing process from the second annealing process. Various examples of the first, second, and third annealing processes will be described with respect to FIGS. 6A-6F. It will of course be understood that, although 1-3 different anneal phases are illustrated and discussed, greater numbers of anneal phases can be included. After the third annealing process, at least a portion of the rapid growth structure 40′ can remain as a rapid growth structure 40″. In other words, some of the grain configurations characteristic of RTP anneal can remain near the bond interface 18 of the conductive features. In some embodiments, the rapid growth structure 40″ can include a stress gradient and/or a gradient of interdiffused metal atoms.

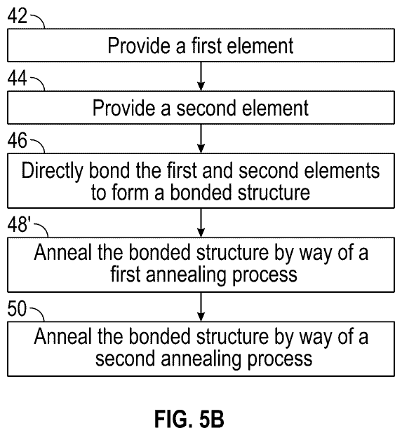

FIG. 5A is a flow chart showing a method of forming a bonded structure according to an embodiment. At block 42, a first element can be provided. The first element can include a first non-conductive field region and a first conductive feature. The first element can be prepared for hybrid direct bonding, with a bonding layer including the first non-conductive field region and the first conductive feature, as well as planarization, activation and/or termination, as disclosed herein.

At block 44, a second element can be provided. The second element can include a second non-conductive field region and a second conductive feature. The second element can be prepared for hybrid direct bonding, with a bonding layer including the second non-conductive field region and the second conductive feature, as well as planarization, activation and/or termination, as disclosed herein.

At block 46, the first element and the second element can be directly bonded to one another to form a bonded structure. The first non-conductive field region is directly bonded to the second non-conductive field region without an intervening adhesive, and the first conductive feature is aligned with the second conductive feature. Alignment need not be perfect. In some embodiments, the bonded structure can be annealed at a low temperature to strengthen the nonconductive-to-nonconductive bond between the first non-conductive field region and the second non-conductive field region. The temperature of the low temperature anneal can be less than 200 °C, or less than 150 °C. At block 46, direct contact between the first and second conductive features are not formed.

At block 48, the bonded structure can be heated or annealed by way of an annealing process to form contact between the first and second conductive features. The annealing process can comprise a rapid thermal process (RTP). As described above, such RTP can be implemented by radiant heating. Including attendant overhead (substrate loading, purging, temperature ramping up, temperature ramping down, substrate unloading), the annealing process at block 48 can be in a range of 4 minute to 8 minutes. Excluding overhead, the actual high temperature plateau portion of the annealing process at block 48 may be, for example, less than 10 seconds, 7 seconds, 5 seconds, or 3 seconds for contact to be formed. The bonded structure can be annealed for a longer duration (e.g., 10 seconds to 20 minutes) for forming more contact between the first and second conductive features.

FIG. 5B is a flow chart showing another method of forming a bonded structure according to an embodiment. Blocks 42-48′ can be as described above with respect to blocks 42-48 in FIG. 5A. At block 50, the bonded structure can be heated or annealed by way of a second annealing process. The second annealing process can comprise a second RTP phase and/or a non-RTP heating phase. A non-RTP heating process for block 50 can include, for example, a convection heating process or a conduction heating process that does not use radiant energy for heating the bonded structure. A total duration of the second annealing process can be longer than a total duration of the first annealing process. The second annealing process can enable the conductive contact formed in the first annealing process to grow and form a more reliable electrical connection between the first and second conductive features. The methods of forming the bonded structure described with respect to FIGS. 5A-5B can be implemented in a wafer-to-wafer (W2W) direct bonding, die-to-wafer (D2W) direct bonding, and die-to-die (D2D) direct bonding. A total duration for forming the bonded structure, including the first and second annealing process can be in a range of 4 minutes to 120 minutes.

The RTP of the first annealing process 48 can enable the first and second conductive features to make contact relatively quickly. Without being limited to theory, the rapid growth structures 40 described above may facilitate early contact during anneal by RTP. The early contact between the first and second conductive features can reduce the duration of the second annealing process to make a desired final structure, including strengthened contact between conductive features and non-conductive features, compared to a process within the first annealing process 48. The first annealing process can enable the total duration of annealing process(es) to be shortened as compared to a conventional annealing process. Thus, various embodiments disclosed herein can enable manufacture of a bonded structure with a lower thermal budget than conventional methods.

FIGS. 6A-6D show various steps in a process of annealing a bonded structure 7a-7d according to an embodiment. FIGS. 6A-6D are generally similar to FIGS. 3A-4C. FIGS. 6B and 6C illustrate extensions 60, 60′ as examples of the rapid growth structures 40, 40′ of FIGS. 4A and 4B.

The bonded structure 7a of FIG. 6A, which can be formed by room temperature contact without external pressure, can be subsequently annealed by way of an RTP to form an initial contact between the first and second conductive features 22, 26 as shown in FIG. 6B. As a result of the RTP, the extensions 60, such as localized spikes, can be formed at the bond interface 18 between the first and second conductive features 22, 26. In a subsequent second annealing process, the result of which is shown in FIG. 6C, the bonded first and second conductive features 22, 26 can grow and/or interdiffuse to define the extensions 60'. In some embodiments, the second annealing process can be a separate, longer conventional anneal (e.g., conductive or convective heating), in the same tool or in a different tool. In other embodiments, a more prolonged plateau in an RTP anneal may form the larger interface of the extensions 60'. In some embodiments, the extensions 60′ may progress through diffusion to a rapid growth structure 60'′ shown in FIG. 6D through a third anneal or extension of the second anneal. Such extensions 60'′ may not be easily distinguished visually from merged conductors due to additional interdiffusion, but may nevertheless be present as a stress gradient and/or a gradient of interdiffused metal atoms in the bonded structure 7d. In other words, characteristic structures that result from the initial RTP treatment may still be detectible in microstructures, such as grain structure or compositional profiles, at the resultant interface 18 between the bonded conductive features 22, 26.

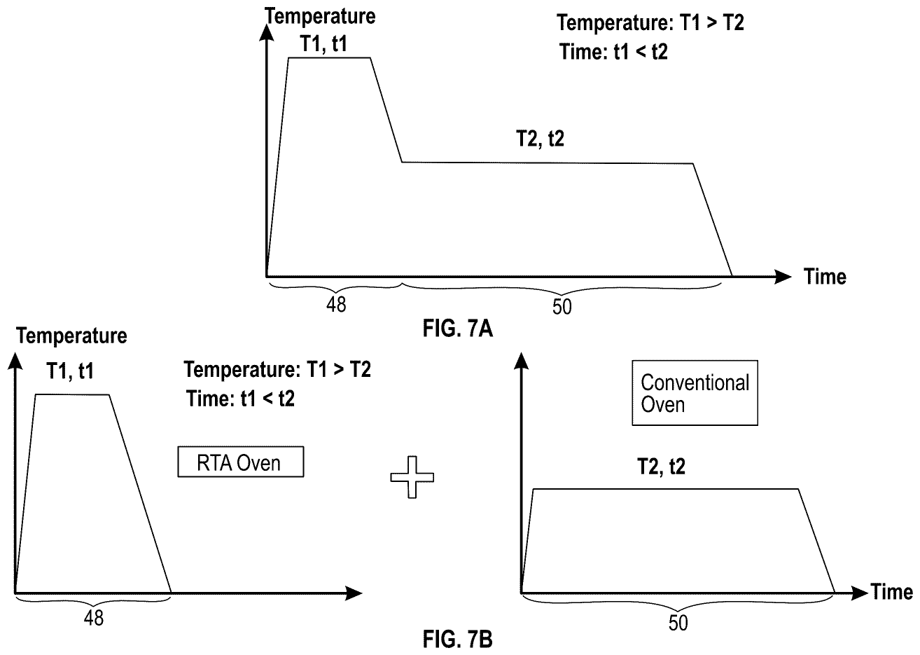

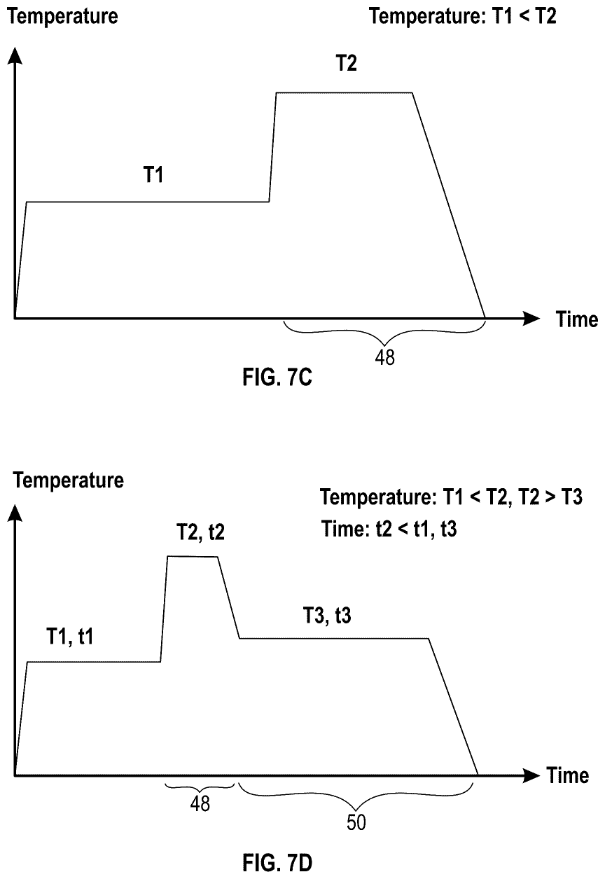

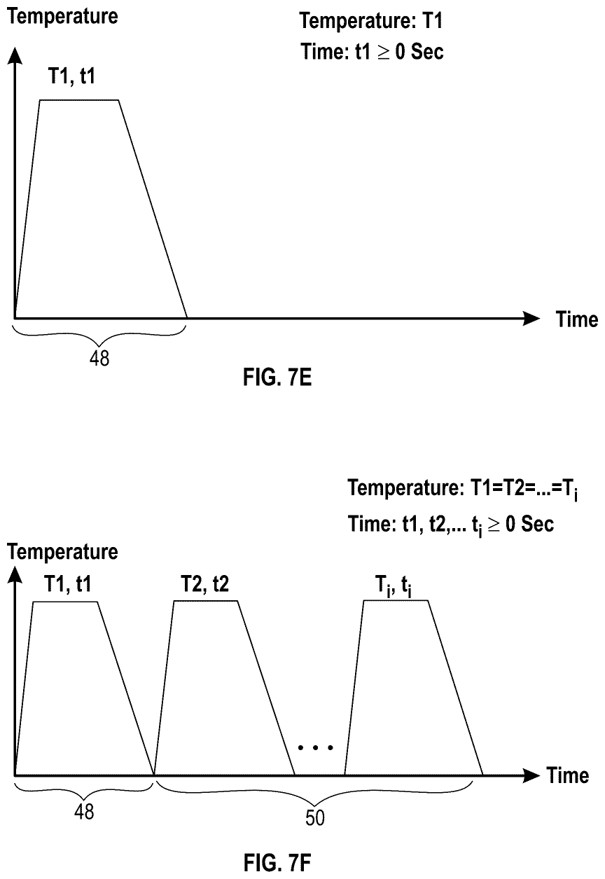

FIGS. 7A-7F show annealing temperatures and annealing times of various annealing processes. The various annealing processes of FIGS. 7A-7F can use the RTP with or without additional non-RTP heating processes as disclosed herein. Components shown in FIG. 3A-4C will be referred to for describing FIGS. 7A-7F.

FIG. 7A shows temperature and time in an annealing process that includes continuous first and second annealing processes 48, 50. For example, a system such as the heating system shown in FIG. 2B, or other tools with multiple heating mechanisms, can be used. The annealing process can include a short RTP heating process followed by a longer non-RTP heating process. The bonded structure 4a, formed, for example, by room temperature contact without external pressure between elements prepared for direct hybrid bonding, can be annealed at peak temperature T1 by way of the RTP for a duration of t1 that is sufficiently long to form an initial contact between the first and second conductive features 22, 26. For example, the duration t1 can be in a range of 0.5 seconds to 5 minutes, 1 second to 1 minute, or 1 second to 10 seconds. The peak temperature for the RTP phase (first anneal 48) can be between about 200 °C and 500 °C, more particularly between about 250 °C and 400 °C Before and after the plateau for duration t1, the RTP phase also includes temperature ramp up and ramp down periods. The ramp up time may be between about 1 seconds and 20 seconds, more particularly between about 5 seconds and 10 seconds. The ramp down time may be between about 30 seconds and 300 seconds, more particularly between about 60 seconds and 180 seconds. The ramp rates during these portions of the RTP phase can be between about 10 °C/second and 150 °C/second, more particularly between about 15 °C/second and 50 °C/second. The ramp rate during temperature increase may be higher (e.g., 50-100 °C/second) compared to during temperature decrease (e.g., 10-30 °C/second). In some embodiments, a rapid growth structure, such as local grain extensions, can be formed by the first annealing process 48.

The bonded structure 4b can be annealed at peak temperature T2 by way of the non-RTP heating process (e.g., conductive or convective heating) for a duration of t2. The duration t2 can be greater than the duration t1. The duration t2 of the second anneal 50 can be between about 10 minutes and 180 minutes, more particularly between about 30 minutes and 120 minutes. The peak temperature for the non-RTP phase (second anneal 50) can be between about 120 °C and 300 °C, more particularly between about 150 °C and 250 °C.

In FIG. 7B, the first and second processes 50 of FIG. 6A are separated, representing conducting the two anneals in separate tools with intervening transfer of the bonded structure 4b, 4c, or 4d (see FIGS. 4A-4C) after the first anneal, but can otherwise have durations, temperatures and ramp rates as described above.

In FIG. 7C the bonded structure 4a can be pre-annealed at a low temperature T1, such as a temperature in a range between about 80 °C and 200 °C, more particularly between about 120 °C and 180 °C, and the first annealing process can follow. The pre-anneal can strengthen nonconductive-to-nonconductive bonding between the first and second non-conductive field regions 20, 24, relative to the bond formed at room temperature without external pressure. The first and second conductive features 22, 26 can be bonded to one another with a greater bond strength by the first annealing process, but the conductive features 22, 26 can remain separated as shown in FIG. 3A. The pre-anneal process can be conducted either in the RTP tool using radiant heating, or in a non-RTP zone or separate tool using, e.g., conductive or convective heating. The pre-anneal can have a duration between about 60 seconds and 1800 seconds, more particularly between about 300 seconds and 900 seconds. Subsequently the “first” anneal 48 process, using RTP, can be conducted. The first anneal 48 or RTP can be conducted with the durations, temperatures and ramp rates as described above with the exception that the initial temperature T1 at the beginning of the ramp up to T2 may be higher if both anneals are conducted in situ in the same tool.

FIG. 7D is similar to FIG. 7C except that in FIG. 7D, the second annealing process 50 follows after the first annealing process 48 shown in FIG. 7C. In FIG. 7D, the bonded structure 4a can be pre-annealed at temperature T1 for a duration t1, and annealed by way of the RTP at peak temperature T2 for a duration of t2 that is shorter than the duration t1 to form the bonded structure 4b. The bonded structure 4b can be annealed by way of the non-RTP heating process (second anneal 50) at temperature T3 for a duration of t3 that is greater than the duration t2. T1, t1, T2, and t2 can be as described for FIG. 7C. T3, t3 can be as described above for T2, t2 with respect to FIG. 7A.

FIG. 7E is similar to FIG. 7C except that in FIG. 7E, the pre-anneal of FIG. 7C is omitted. In FIG. 7E, the first annealing process 48 comprises the RTP and no non-RTP anneal is employed. Instead, the short RTP is employed at peak temperature T1 for duration t1 that is a minimum required to reliably form electrical connections between corresponding conductive features 22, 26 for device requirements. The anneal 48 or RTP can be conducted with the durations, temperatures and ramp rates as described above with respect to FIG. 7A.

FIG. 7F shows a first annealing process that comprises the RTP followed by a second annealing process that comprises a plurality of RTPs. As described above, the first annealing process can form an initial contact between the first and second conductive features 22, 26, and the second annealing process can grow and/or interdiffuse the bonded first and second conductive features 22, 26, thereby improving electrical connection and bond interface quality. Rather than conductive and/or convective heating in subsequent anneals, the embodiment of FIG. 7F employs multiple pulses of RTP for the anneals to complete the bonds between conductive features 22, 26. Each pulse can have durations, temperatures and ramp rates as described above with respect to the first anneal 48 of FIG. 7A, or can each have different parameters as determined through routine experimentation in view of the teachings herein.

A suitable annealing process and a suitable annealing duration can be selected based at least in part on the materials and dimensions of various components of a bonded structure.

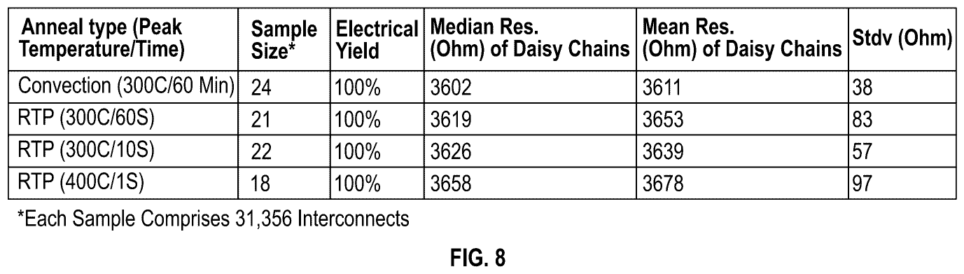

FIG. 8 is a chart showing experimental results indicating reliability of die-to-wafer (D2W) bonded structures formed using four different annealing processes. The four annealing processes include (1) a convection heating for 120 minutes at 150 °C followed by a convection heating for 60 minutes at a peak temperature of 300 °C; (2) the RTP for 60 seconds at a peak temperature of 300 °C, with a ramp-up rate of 100 °C/min and a ramp-down rate of 20 °C/min; (3) the RTP for 10 seconds with a peak temperature of 300 °C, with a ramp-up rate of 25 °C/s; and (4) the RTP for 1 second with a peak temperature of 400 °C, with a ramp-up rate of 67 °C/s and an active cooling using a nitrogen gas flow. The chart of FIG. 8 shows a sample size, electrical yield, a median resistance, a mean resistance, and a standard deviation of the measured resistances of the bonded structures. These results indicate that the RTP can achieve sufficient conductive-to-conductive connection in hybrid directly bonded structures. These results indicate that the RTP alone can make reliable electrical connections across the bonded structures, despite known issues with temperature uniformity with RTP. When combined with a conventional anneal, the RTP can enable considerable reduction in the overall anneal time while still forming more complete physical connections across the bonded structures.

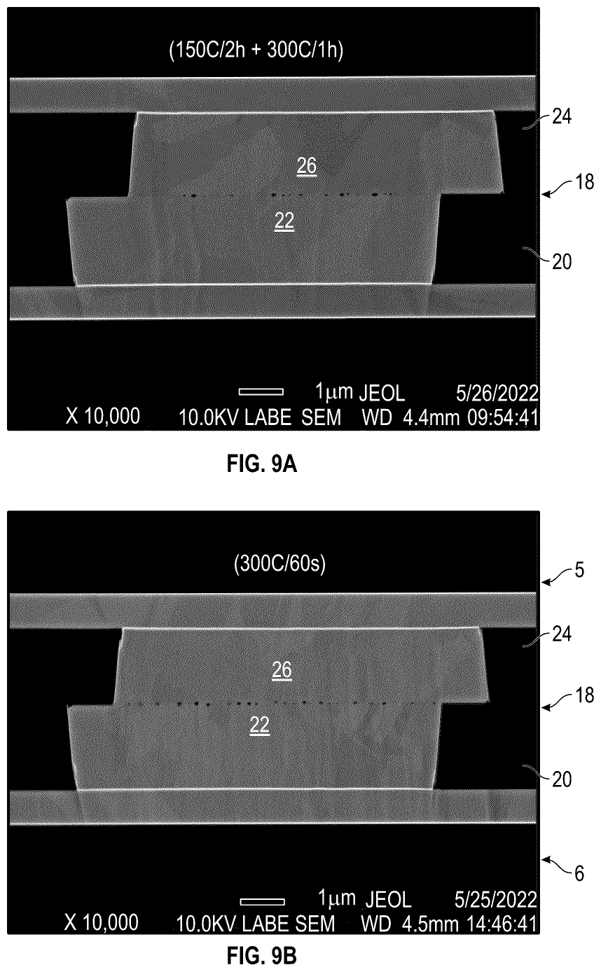

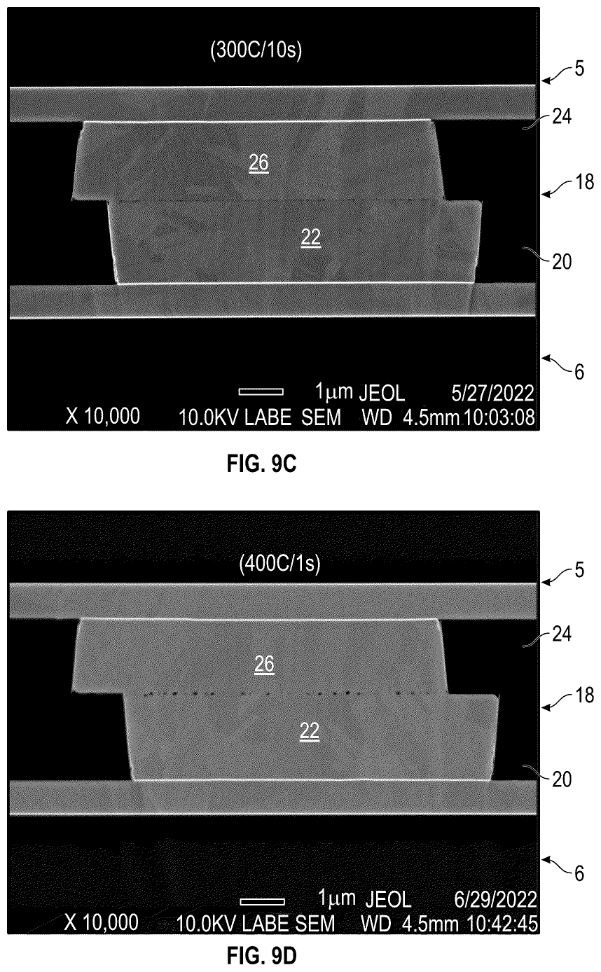

FIGS. 9A-D show scanning electronic microscopy (SEM) images of four bonded structures formed in accordance with the four processes described above with respect to FIG. 8. The SEM images show that a reliable bonding along a bond interface 18 between first and second elements 5, 6 can be formed in a shorter time using the RTP as compared to using a conventional convection heating. The RTP quickly creates high density small connections (e.g., the extensions 60 as described herein) along the bond interface 18. In some embodiments, an additional thermal budget (e.g., a longer heating duration and/or a higher temperature) can result in coalescence of small voids at the bond interface 18 into larger but fewer voids.

A thermal treatment process can include a preparation process, an annealing process (e.g., one or more rapid thermal processes (RTPs) as disclosed herein), and a cooling process. For example, the preparation process can include loading a bonded structure (e.g., the bonded structure 4a shown in FIG. 3) into a thermal processing system. The preparation process may also include purging the system or chamber into which the bonded structure is loaded. In the annealing process, the bonded structure 4a can be annealed to form an annealed bonded structure (e.g., the bonded structure 4b, 4c, 4d, 7a, 7b, 7c, 7d of FIGS. 4A-4C, and 6A-6D). In the cooling process, the annealed bonded structure can be cooled prior to unloading to complete the thermal treatment process. In some embodiments, the cooling process can comprise active cooling.

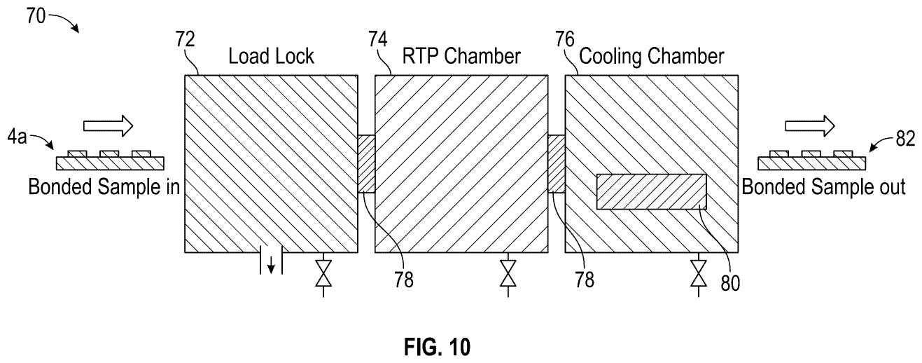

FIG. 10 schematically shows an example thermal treatment system 70. The thermal treatment system 70 can include a load lock 72, a rapid thermal process (RTP) chamber 74, and a cooling chamber 76. The load lock 72, the RTP chamber 74, and the cooling chamber 76 can be connected, for example, by isolation valves 78. A bonded structure 4a can be provided in the load lock 72 in a preparation process. After the preparation process, the bonded structure 4a can be provided in the RTP chamber 74 for annealing to provide an annealed bonded structure 82 (e.g., the bonded structure 4b, 4c, 4d, 7a, 7b, 7c, 7d of FIGS. 4A-4C, and 6A-6D). The annealed bonded structure 82 can be cooled in the cooling chamber 76.

In some embodiments, the load lock 72 can be a vacuum chamber. The load lock 72 can transfer the bonded structure 4a between two environments with different levels of cleanliness or atmospheric conditions. For example, the two environments can be the RTP chamber 74 and an outside environ of the RTP chamber 74. Implementing the load lock 72 can contribute to increasing throughput. In the load lock 72, the bonded structure 4a can be purged with, for example, an inert gas (e.g., nitrogen (N2)). Although shown as directly communicating with the RTP chamber 74, the skilled artisan will appreciate that the load lock 72 can communicate substrates through an isolatable transfer chamber, and that such a transfer chamber can directly communicate substrates (through gate valves) to each of the RTP chamber 74 and the cooling chamber 76, rather than directly connecting the two chambers 74, 76. Additionally, convective or conductive ovens can also be provided in a cluster tool to add multiple anneal phases to the process as described herein.

In the RTP chamber 74, any one or more of the annealing processes disclosed herein can be conducted. The annealing process(s) in the RTP chamber 74 can directly bond the first and second conductive features 22, 26 of the bonded structure 4a to be bonded, thereby creating a conductor-to-conductor direct bonding.

In some embodiments, the cooling chamber 76 can include an actively cooled chuck 80 that has a cooling mechanism integrated or coupled therewith. The annealed bonded structure 82 can be held by the actively cooled chuck 80 to reduce the temperature of the annealed bonded structure 82 to a desired temperature. In some embodiments, the annealed bonded structure 82 can be instead or additionally convectively cooled by way of purging in the cooling chamber 76. For example, the annealed bonded structure 82 can be purged with a cooled inert gas (e.g., nitrogen (N₂)). The actively cooled chuck 80 and/or the purge cooling can enable the annealed bonded structure 82 to be cooled more quickly than natural or passive cooling, thereby reducing the thermal budget. The skilled artisan will appreciate that after cooling the annealed bonded structure 82 can be unloaded through a separate isolation valve, or back through the load lock chamber 72 (by way of the intervening RTP chamber 78, or through any intervening transfer chamber).

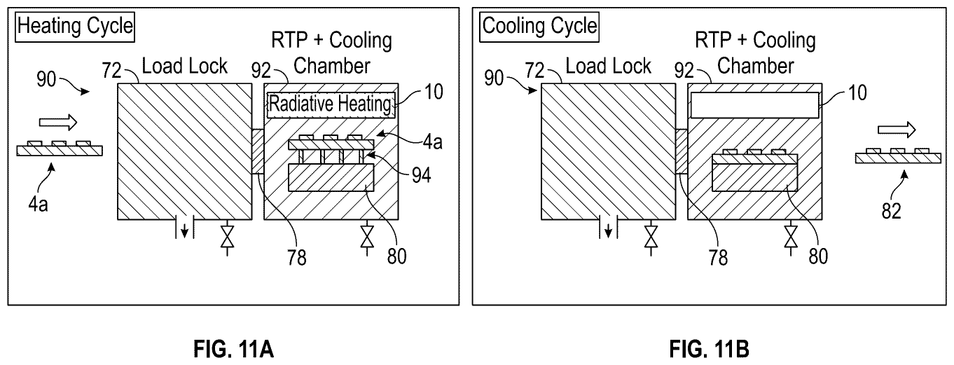

FIG. 11A shows a thermal treatment system 90 in a first state (a heating cycle). FIG. 11B shows the thermal treatment system 90 in a second state (a cooling cycle). The thermal treatment system 90 can include a load lock 72 and an annealing chamber 92. The load lock 72 and the annealing chamber 92 can be connected, for example, by an isolation valve 78, and can also include an intervening transfer chamber for more complex cluster tools. The annealing chamber 92 can function as both the RTP chamber 74 and the cooling chamber 76 shown in FIG. 10.

The annealing chamber 92 can include a heat source 10 (e.g., lamps or laser sources as described above), and a cooling mechanism (e.g., the actively cooled chuck 80). In the first state (the heating cycle), the bonded structure 4a can be spaced apart from the actively cooled chuck 80 by way of, for example, pins 94 or pillars that can extend between the actively cooled chick 80 and the bonded structure 4a. In the second state (the cooling cycle), the bonded structure 4a can be closer to (e.g., in contact with) the actively cooled chuck 80. The pins 94 can lift and descend the bonded structure 4a relative to the actively cooled chuck 80. The load lock 72 and the annealing chamber 92 can contribute to increasing throughput, and the active cooling mechanism (e.g., the actively cooled chuck 80) and/or the purge cooling can enable the annealed bonded structure 82 to be cooled more quickly than natural or passive cooling, thereby reducing the thermal budget. The purge cooling as described with respect to FIG. 10 may be employed in place of or in addition to the actively cooled chuck 80. As also noted with respect to FIG. 10, the annealed bonded structure 82 can be unloaded by way of the load lock 72 and any intervening chamber.

In one aspect, a method of forming a bonded structure is disclosed. The method includes providing a first element including a first non-conductive field region and a first conductive feature, and directly bonding the first element to a second element. The second element includes a second non-conductive field region and a second conductive feature such that the first non-conductive field region is directly bonded to the second non-conductive field region without an intervening adhesive. The first conductive feature is aligned with the second conductive feature. The method also includes, after directly bonding the first element to the second element, annealing the first and second elements by way of rapid thermal process.

In some embodiments, after directly bonding the first element to the second element and before annealing the first and second elements by way of rapid thermal process, the first and second conductive features are spaced by a gap. The gap between the first and second conductive features can be bridged by expansion of the first and second conductive features due to the rapid thermal process. The method can further include annealing the first and second elements by way of a convection or conduction heating process to strengthen a bonding strength between the first non-conductive field region and the second non-conductive field region prior to annealing the first and second elements by way of rapid thermal process. The method can further include annealing the first and second elements by way of a convection or conduction heating process after electrically connecting the first and second conductive features for a duration that is longer than a duration of the rapid thermal process.

In one embodiment, annealing the first and second elements by way of rapid thermal process includes forming a rapid growth structure connecting the first conductive feature to the second conductive feature in multiple locations.

In some embodiments, the rapid thermal process includes heating the bonded first and second elements by way of a radiant energy source. The radiant energy source can include radiant heat lamps. The radiant heat lamps can include infrared halogen lamps.

In some embodiments, the first element further includes a first device portion and the second element further includes a second device portion. The first device portion can include an optoelectronic single crystal material. The second device portion can include silicon (Si), quartz, fused silica glass, sapphire, or a glass. The first device portion can include lithium tantalate (LiTaO₃) or lithium niobate (LiNbO₃).

In one embodiment, the method further includes, after directly bonding the first element to the second element and prior to annealing the first and second elements, providing the first and second elements in a load lock.

In one embodiment, the method further includes, after annealing the first and second elements, actively cooling the first and second elements.

In another aspect, a method of direct bonding is disclosed. The method includes directly bonding non-conductive regions of a first element to non-conductive regions of a second element to form a bonded structure. The method includes, after directly bonding the non-conductive regions, annealing the bonded structure to bridge a gap between aligned conductive features of the first element and the second element in the bonded structure. Annealing includes exposing the bonded structure to radiant heating.

In one embodiment, the method further includes polishing a bonding surface of the first element to have a surface roughness in a range of 1 Å rms to 15 Å rms.

In one embodiment, annealing the bonded structure further includes exposing the bonded structure to a convection or conduction heating process prior to exposing the bonded structure to radiant heating.

In one embodiment, annealing the bonded structure further includes exposing the bonded structure to a convection or conduction heating process after exposing the bonded structure to the radiant heating. Exposing to the convection or conduction heating process can be conducted for a duration that is longer than a duration of exposing to the radiant heating at a temperature that can be lower than a peak temperature of the bonded structure during exposing to the radiant heating.

In one embodiment, exposing the bonded structure to the radiant heating includes forming extensions between the aligned first and second conductive features of the first and second elements.

In some embodiments, annealing the bonded structure includes annealing the bonded structure for a duration in a range of 0.5 seconds to 5 minutes at a maximum temperature in a range of 200 °C to 500 °C. A ramp up rate during exposing the bonded structure to radiant heating before reaching the maximum temperature can be in a range of 10 °C per second to 150 °C per second.

In one embodiment, a majority of the first element includes a first material having a first coefficient of thermal expansion and a majority of the second element includes a second material having a second coefficient of thermal expansion that is at least 5 ppm different from the first coefficient of thermal expansion.

In another aspect, a method of forming a bonded structure is disclosed. The method includes providing a first element including a first surface dielectric region and surface metal region, and directly bonding the first element to a second element. The second element includes a second surface dielectric region and a second surface metal region such that the first surface dielectric region is directly bonded to the second surface dielectric region without an intervening adhesive. The first surface metal region is aligned with the second surface metal region. The method also includes, after directly bonding the first element to the second element, annealing the first and second elements by way of an annealing process thereby providing a conductive contact between the first and second surface metal regions. The annealing process includes a phase with a ramp up rate in a range of about 10 °C per second to 150 °C per second.

In one aspect, a bonded structure is disclosed. The bonded structure includes a first element including a first non-conductive field region and a first conductive feature. The bonded structure includes a second element including a second non-conductive field region and a second conductive feature. The second element is directly bonded to the first element along a bond interface such that the first non-conductive field region is directly bonded to the second non-conductive field region without an intervening adhesive. The first conductive feature is directly bonded to the second conductive feature without an intervening adhesive. The bond interface between the first and second conductive features includes a rapid growth structure indicative of annealing by a rapid thermal process.

In one embodiment, the rapid growth structure includes a plurality of grain extensions between the first and second conductive features.

In one embodiment, the rapid growth structure includes a stress gradient and/or a gradient of interdiffused metal atoms.

In some embodiments, the first element is a wafer or a die. The second element can be a wafer or a die.

In one embodiment, the first element further includes a first device portion and the second element includes a second device portion. The first device portion can include a first material having a first coefficient of thermal expansion and the second device portion can include a second material having a second coefficient of thermal expansion that is at least 5 ppm different from the first coefficient of thermal expansion.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A method of forming a bonded structure, the method comprising:
providing a first element including a first non-conductive field region and a first conductive feature;
directly bonding the first element to a second element, the second element including a second non-conductive field region and a second conductive feature, such that the first non-conductive field region is directly bonded to the second non-conductive field region without an intervening adhesive, and the first conductive feature is aligned with the second conductive feature; and
after directly bonding the first element to the second element, annealing the first and second elements by way of rapid thermal process.

2. The method of claim 1, wherein after directly bonding the first element to the second element and before annealing the first and second elements by way of rapid thermal process, the first and second conductive features are spaced by a gap.

3. The method of claim 2, wherein the gap between the first and second conductive features is bridged by expansion of the first and second conductive features due to the rapid thermal process.

4. The method of claim 3, further comprising annealing the first and second elements by way of a convection or conduction heating process to strengthen a bonding strength between the first non-conductive field region and the second non-conductive field region prior to annealing the first and second elements by way of rapid thermal process.

5. The method of claim 3, further comprising annealing the first and second elements by way of a convection or conduction heating process after electrically connecting the first and second conductive features for a duration that is longer than a duration of the rapid thermal process.

6. The method of claim 1, wherein annealing the first and second elements by way of the rapid thermal process comprises forming a rapid growth structure connecting the first conductive feature to the second conductive feature in multiple locations.

7. The method of claim 1, wherein a temperature ramp rate during annealing the first and second elements by way of the rapid thermal process is in a range of 10 °C per second to 150 °C per second.

8. The method of claim 1, wherein annealing the first and second elements by way of the rapid thermal process comprises exposing the first and second elements to infrared halogen lamps.

9. The method of claim 1, wherein the first element further comprises a first device portion and the second element further comprises a second device portion, the first device portion including an optoelectronic single crystal material, and the second device portion including silicon (Si), quartz, fused silica glass, sapphire, or a glass.

10. The method of claim 9, wherein the first device portion comprises lithium tantalate (LiTaO₃) or lithium niobate (LiNbO₃).

11. The method of claim 1, further comprising, after directly bonding the first element to the second element and prior to annealing the first and second elements, providing the first and second elements in a load lock.

12. The method of claim 1, further comprising, after annealing the first and second elements, actively cooling the first and second elements.

13. A method of forming a bonded structure, the method comprising:
providing a first element including a first surface dielectric region and surface metal region;
directly bonding the first element to a second element, the second element including a second surface dielectric region and a second surface metal region, such that the first surface dielectric region is directly bonded to the second surface dielectric region without an intervening adhesive, and the first surface metal region is aligned with the second surface metal region; and
after directly bonding the first element to the second element, annealing the first and second elements by way of an annealing process thereby providing a conductive contact between the first and second surface metal regions, the annealing process including a phase with a ramp up rate in a range of about 10 °C per second to 150 °C per second.

14. A bonded structure, comprising:
a first element including a first non-conductive field region and a first conductive feature; and
a second element including a second non-conductive field region and a second conductive feature, the second element directly bonded to the first element along a bond interface such that the first non-conductive field region is directly bonded to the second non-conductive field region without an intervening adhesive, and the first conductive feature is directly bonded to the second conductive feature without an intervening adhesive,
wherein the bond interface between the first and second conductive features comprises a rapid growth structure indicative of annealing by a rapid thermal process.

15. The bonded structure of claim 14, wherein the rapid growth structure comprises a plurality of grain extensions between the first and second conductive features.

16. The bonded structure of claim 14, wherein the rapid growth structure comprises a stress gradient and/or a gradient of interdiffused metal atoms.

17. The bonded structure of claim 14, wherein the first and second elements are wafers.

18. The bonded structure of claim 14, wherein the first and second elements are dies.

19. The bonded structure of claim 14, wherein the first element is a wafer and the second element is a die.

20. The bonded structure of claim 14, wherein the first element further comprises a first device portion and the second element comprises a second device portion, the first device portion comprises a first material having a first coefficient of thermal expansion and the second device portion comprises a second material having a second coefficient of thermal expansion that is at least 5 ppm different from the first coefficient of thermal expansion.
